(19) United States
(12) Patent Application Publication
(10) Pub. No.: US 2016/0291375 A1
(43) Pub. Date: Oct. 6, 2016

(54) DISPLAY SUBSTRATE, METHOD FOR MANUFACTURING THE SAME, AND LIQUID CRYSTAL DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Weixin Meng, Beijing (CN); Yuguang Fan, Beijing (CN); Yuekai Gao, Beijing (CN); Yongshan Zhou, Beijing (CN)

(21) Appl. No.: 15/083,550

(22) Filed: Mar. 29, 2016

(30) Foreign Application Priority Data
Apr. 1, 2015 (CN) 201510151957.0

(51) Int. Cl. G02F 1/1339; G02F 1/1335; H01L 27/12

(52) U.S. Cl. CPC G02F 1/13394; H01L 27/124; H01L 27/1259; G02F 1/1339; G02F 1/133514; G02F 1/133516

(57) ABSTRACT

A display substrate includes at least two substrate regions to be cut which is arranged in an array; a seal agent which is disposed on a surface of the display substrate and is coated around the substrate region to be cut; and a barrier wall which is disposed between adjacent substrate regions to be cut and is configured to block the seal agent. A method for manufacturing the display substrate and a liquid crystal display device comprising the display substrate are further disclosed.

### TECHNICAL FIELD

Embodiments of the present disclosure relate to a display substrate and a method for manufacturing the same as well as a liquid crystal display device.

### BACKGROUND

By development in recent decades of years, technique and process of Thin Film Transistor-Liquid Crystal Display (abbreviated as TFT-LCD) technology have been well-developed. By taking the place of Cold Cathode Fluorescent Lamp (abbreviated as CCFL) display, it has become the mainstream product in the display field.

Typically, in mobile display products, it is defined as a bezel from a display region to a border of the display screen. Existence of the bezel reduces visual effect of the whole display screen. The larger the bezel region is, the poorer the visual effect will be. Therefore, visual effect of a narrow bezel or even no bezel become a trend for high quality display screens.

However, as the size of TFT-LCD panel becomes smaller and smaller, in liquid crystal dropping process, liquid crystal molecules may be in contact with uncured seal agent after liquid crystals drop down and before curing the seal agent by ultraviolet light, so that a phenomenon in which the liquid crystals and the seal agent are contaminated by each other and the liquid crystal molecules penetrate the seal agent may occur. Especially for products of narrow bezel, there is a very small distance or even no distance between seal agents of two adjacent substrates to be cut, which easily causes a flow between adjacent seal agents and an uneven distribution of seal agent and thus affects the cutting of panels which further results in failure in separation of display panels and even leakage of liquid crystals.

### SUMMARY

At least one embodiment of the present disclosure provides a display substrate, comprising at least two substrate regions to be cut which are arranged in an array;

a seal agent which is disposed on a surface of the display substrate and are coated around the substrate regions to be cut; and a barrier wall which is disposed between adjacent substrate regions to be cut and is configured to block the seal agent.

At least one embodiment of the present disclosure provides a method for manufacturing a display substrate, comprising:

forming a barrier wall on a surface of the display substrate which comprises at least two substrate regions to be cut which is arranged in an array, the barrier wall being disposed between adjacent substrate regions to be cut; and

coating a seal agent around the substrate region to be cut.

At least one embodiment of the present disclosure provides a liquid crystal display device comprising a pair of display substrates which are cell-assembled, and at least one of which is the display substrate as described above.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative structural view of a display substrate according to one embodiment of the present disclosure;

FIG. 2 is a structural section view of a display substrate according to one embodiment of the present disclosure;

FIG. 3 is a structural section view of a display substrate according to another embodiment of the present disclosure;

FIG. 4 is a illustrative flowchart of a method for manufacturing a display substrate according to one embodiment of the present disclosure;

FIG. 5 is a flowchart of making a barrier wall in the method for manufacturing a display substrate according to one embodiment of the present disclosure; and

FIG. 6 is an illustrative flowchart of making a barrier wall in the method for manufacturing a display substrate according to another embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

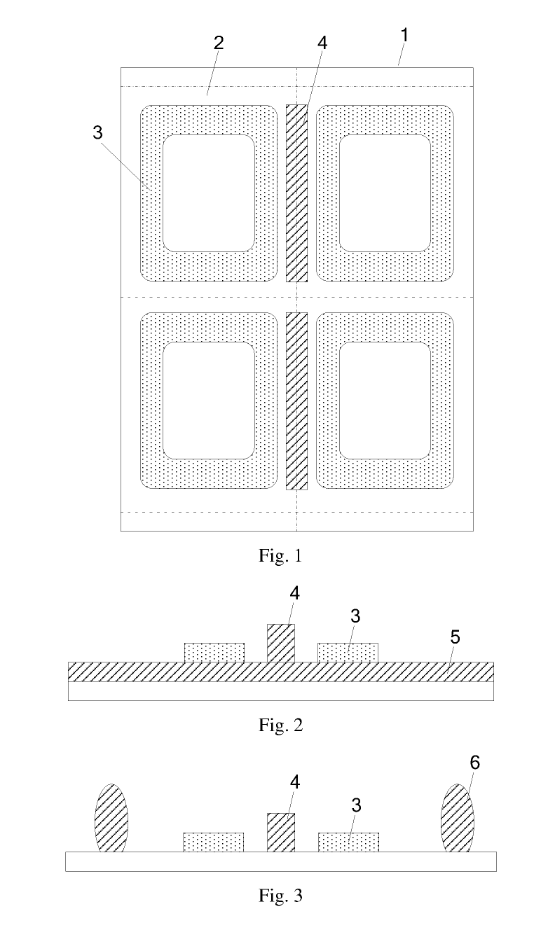

At least one embodiment of the present disclosure provides a display substrate 1. As illustrated in FIG. 1, the display substrate 1 comprises at least two substrate regions to be cut 2 which are arranged in an array; a seal agent 3 which is disposed on a surface of the display substrate 1 and are coated around the substrate regions 2 to be cut; and barrier walls 4 which are disposed between adjacent substrate regions to be cut 2 and are configured to block the seal agents.

The display substrate according to the embodiment of the present disclosure comprises at least two substrate regions to be cut which is arranged in an array. On the surface of the display substrate, a seal agent is coated around the substrate region to be cut. The barrier wall configured to block the seal agent is disposed between adjacent substrate regions to be cut. With such a barrier wall structure, by making a barrier wall configured to block the flowing of uncured seal agent on a cutting line at the middle of two adjacent substrate regions to be cut, a flow of seal agent can be block and thus an uneven distribution of seal agent due to flow of seal agent can be effectively prevented, thereby ensuring the width of seal agent, and significantly obviating failure in separation of display panels and even leakage of liquid crystals.

In one embodiment of the present disclosure, as illustrated in FIG. 2, the display substrate 1 can be a color filter substrate comprising a color filter structure 5. The barrier wall 4 and the color filter structure 5 can be made of the same material, and the barrier wall 4 and the color filter structure 5 are formed in the same layer.

For example, in the color filter substrate as illustrated in FIG. 2, the color filter structure 5 can comprise sub-pixels with red, green and blue (RGB) colors, the pixels of each color are respectively formed on a surface of a transparent substrate through one patterning process. Material of the barrier wall 4 can be the same as that of any sub-pixels among RGB sub-pixels, so that the barrier wall 4 and the sub-pixels of the particular color can be simultaneously formed by one patterning process when making such sub-pixels. In this way, the barrier wall 4 can be formed without introducing an additional process, thereby significantly reducing production cost of the display substrate with such a structure. Of course, the above is merely an illustration by way of examples, the color filter structure 5 can be of a structure with sub-pixels of only one color or comprising sub-pixels of colors, which will not be enumerated herein.

The display substrate according to one embodiment of the present disclosure is illustrated in FIG. 3 and a spacer 6 is disposed on the surface of the display substrate. The barrier wall 4 and the spacer 6 can be made of the same material, and the barrier wall 4 and the spacer 6 can be formed in the same layer.

In the display substrate as illustrated in FIG. 3, a spacer material layer can be formed on the surface of the display substrate, and the barrier wall 4 and the spacer 6 can be simultaneously formed on the spacer material layer by one patterning process. In this way, the barrier wall 4 can be created without adding an additional process, thereby significantly reducing production cost of the display substrate having such a structure.

It should be noted that, in the display substrate as illustrated in FIG. 3, the display substrate 1 can be an array substrate or a color filter substrate, and the spacer 6 configured to support thickness of a liquid crystal cell is formed on the surface of the display substrate.

In one embodiment of the present disclosure, the barrier wall 4 can have a length greater than or equal to the length of the substrate region 2 to be cut, and the barrier wall 4 has a width greater than 0.3 μm (micron) and less than 0.5 μm.

With such a barrier wall structure, by disposing a barrier wall configured to block the flowing of uncured seal agent on a cutting line at the middle of two adjacent substrate regions to be cut, a flow of seal agent can be effectively blocked and thus an uneven distribution of seal agent due to flow of seal agent can be prevented, thereby ensuring the width of seal agent, and significantly obviating failure in separation of display panels and even leakage of liquid crystals.

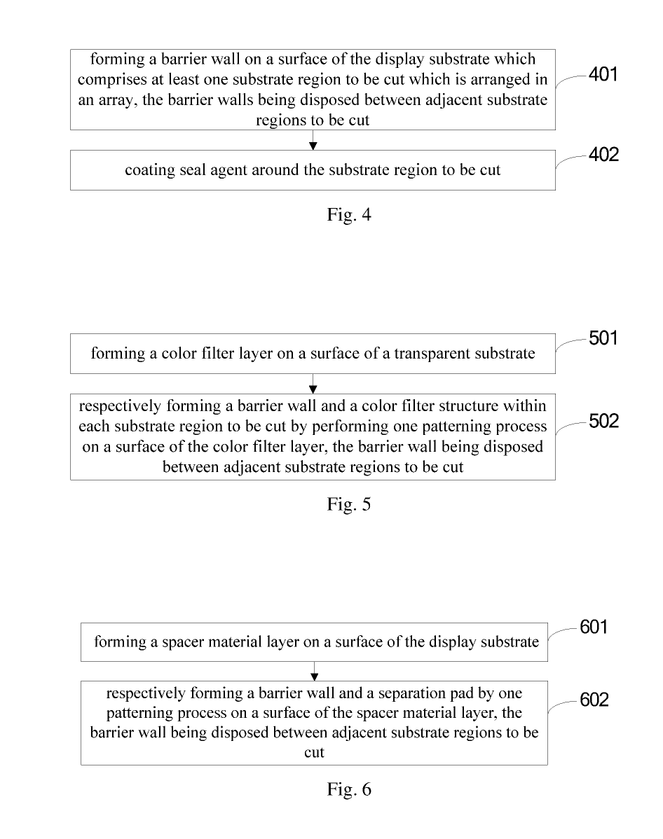

At least one embodiment of the present disclosure provides a method for manufacturing display substrate, as illustrated in FIG. 4, which comprises:

Step 401 of forming a barrier wall on a surface of the display substrate which comprises at least two substrate regions to be cut which is arranged in an array, the barrier walls being disposed between adjacent substrate regions to be cut.

Step 402 of coating a seal agent around the substrate region to be cut.

In the method for manufacturing display substrate according to the embodiment of the present disclosure, the display substrate comprises at least two substrate regions to be cut which is arranged in an array. On the surface of the display substrate, a seal agent is coated around the substrate region to be cut. The barrier wall configured to block the seal agent is disposed between adjacent substrate regions to be cut. With such a barrier wall structure, by disposing a barrier wall configured to block the flow of uncured seal agent on a cutting line at the middle of two adjacent substrate regions to be cut, a flow of seal agent can be effectively blocked and thus an uneven distribution of seal agent due to flow of seal agent can be effectively prevented, thereby ensuring the width of seal agent, and significantly obviating failure in separation of display panels and even leakage of liquid crystals.

As illustrated in FIG. 5, according to one embodiment of the present disclosure, the step of forming a barrier wall on a surface of the display substrate can comprise:

Step 501 of forming a color filter layer on a surface of a transparent substrate.

Step 502 of respectively forming a barrier wall and color filter structures within each substrate region to be cut by performing one patterning process on the color filter layer, the barrier wall being positioned between adjacent substrate regions to be cut.

By simultaneously forming the barrier wall and the color filter structure, the barrier wall can be made without introducing an additional process, thereby significantly reducing production cost of the display substrate having such a structure.

In one embodiment of the present disclosure, as illustrated in FIG. 6, the step of forming a barrier wall on a surface of the display substrate can comprise:

Step 601 of forming a spacer material layer on a surface of the display substrate.

Step 602 of respectively forming a barrier wall and a spacer by performing one patterning process on the spacer material layer, the barrier wall being positioned between adjacent substrate regions to be cut.

By simultaneously forming the barrier wall and the spacer, the barrier wall can be made without introducing an additional process, thereby significantly reducing production cost of the display substrate having such a structure.

In one embodiment of the present disclosure, the barrier wall can have a length greater than or equal to the length of the substrate region to be cut, and the barrier wall has a width greater than 0.3 μm and less than 0.5 μm.

At least one embodiment of the present disclosure provides a liquid crystal display device comprising a pair of display substrates which are cell-assembled (that is, the two display substrates are assembled together via a seal agent to form a liquid crystal cell), wherein at least one display substrate is the display substrate as described above.

The structure of the display substrate has been described in detail in the above-described embodiments, and will not be elaborated here.

The liquid crystal display device can be any product or component with display function such as a cell phone, a tablet PC, a television, a display, a laptop, a digital photo frame, a navigator and etc.

The liquid crystal display device according to the embodiments of the present disclosure comprises a pair of display substrates which are cell-assembled. At least one display substrate comprises at least two substrate regions to be cut which is arranged in an array. On the surface of the display substrate, a seal agent is coated around the substrate region to be cut. The barrier wall configured to block the seal agent is disposed between adjacent substrate regions to be cut. With such a barrier wall structure, by making a barrier wall configured to block the flow of uncured seal agent on a cutting line at the middle of two adjacent substrate regions to be cut, a flow of seal agent can be blocked and thus an uneven distribution of seal agent due to flow of seal agent can be effectively prevented, thereby ensuring the width of seal agent, and significantly obviating failure in separation of display panels and even leakage of liquid crystals.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510151957.0 filed on Apr. 1, 2015, the disclosure of which is hereby entirely incorporated by reference as a part of the present disclosure.

1. A display substrate, comprising:
at least two substrate regions to be cut which is arranged in an array;
a seal agent which is disposed on a surface of the display substrate and is coated around the substrate region to be cut; and
a barrier wall which is disposed between adjacent substrate regions to be cut and is configured to block the seal agent.

2. The display substrate according to claim 1, wherein the display substrate is a color filter substrate which comprises a color filter structure;
the barrier wall is formed in the same layer as the color filter structure and is made of the same material as the color filter structure.

3. The display substrate according to claim 2, wherein the barrier wall and the color filter structure are formed by the same patterning process.

4. The display substrate according to claim 1, wherein the surface of the display substrate comprises a spacer disposed on the surface thereof; and
the barrier wall is formed on the same layer as the spacer and is made of the same material as the spacer.

5. The display substrate according to claim 2, wherein a spacer is disposed on the surface of the display substrate;
the barrier wall is formed in the same layer as the spacer and is made of the same material as the spacer.

6. The display substrate according to claim 1, wherein the barrier wall has a length greater than or equal to a length of the substrate region to be cut, and the barrier wall has a width greater than 0.3 μm and less than 0.5 μm.

7. The display substrate according to claim 2, wherein the barrier wall has a length greater than or equal to a length of the substrate region to be cut, and the barrier wall has a width greater than 0.3 μm and less than 0.5 μm.

8. The display substrate according to claim 3, wherein the barrier wall has a length greater than or equal to a length of the substrate region to be cut, and the barrier wall has a width greater than 0.3 μm and less than 0.5 μm.

9. The display substrate according to claim 4, wherein the barrier wall has a length greater than or equal to a length of the substrate region to be cut, and the barrier wall has a width greater than 0.3 μm and less than 0.5 μm.

10. The display substrate according to claim 5, wherein the barrier wall has a length greater than or equal to a length of the substrate region to be cut, and the barrier wall has a width greater than 0.3 μm and less than 0.5 μm.

11. A method for manufacturing a display substrate, comprising:
forming a barrier wall on a surface of the display substrate which comprises at least two substrate regions to be cut which is arranged in an array, the barrier walls being disposed between adjacent substrate regions to be cut; and
coating a seal agent around the substrate region to be cut.

12. The method for display substrate according to claim 11, wherein forming the barrier wall on the surface of the display substrate comprises:
forming a color filter layer on a surface of a transparent substrate of the display substrate; and
respectively forming a barrier wall and a color filter structure within each substrate region to be cut by performing one patterning process on a surface of the color filter layer.

13. The method for manufacturing display substrate according to claim 11, wherein forming the barrier wall on the surface of the display substrate comprises:
forming a spacer material layer on a surface of the display substrate; and
respectively forming a barrier wall and a spacer by one patterning process on a surface of the spacer material layer.

14. The method for manufacturing display substrate according to claim 11, wherein the barrier wall has a length greater than or equal to a length of the substrate region to be cut, and the barrier wall has a width greater than 0.3 μm and less than 0.5 μm.

15. The method for manufacturing display substrate according to claim 12, wherein the barrier wall has a length greater than or equal to a length of the substrate region to be cut, and the barrier wall has a width greater than 0.3 μm and less than 0.5 μm.

16. The method for manufacturing display substrate according to claim 13, wherein the barrier wall has a length greater than or equal to a length of the substrate region to be cut, and the barrier wall has a width greater than 0.3 μm and less than 0.5 μm.

17. A liquid crystal display device, comprising a pair of display substrates which are cell-assembled, wherein at least one display substrate is the display substrate according to claim 1.

18. A liquid crystal display device, comprising a pair of display substrates which are cell-assembled, wherein at least one display substrate is the display substrate according to claim 2.

19. A liquid crystal display device, comprising a pair of display substrates which are cell-assembled, wherein at least one display substrate is the display substrate according to claim 4.

20. A liquid crystal display device, comprising a pair of display substrates which are cell-assembled, wherein at least one display substrate is the display substrate according to claim 6.
